(19) United States
(12) Patent Application Publication
(10) Pub. No.: US 2009/0016039 A1
(43) Pub. Date: Jan. 15, 2009

(54) Structure And Method For Attaching Shield Case To Circuit Board, Electronic Component Module And Portable Telephone

(75) Inventor: Takashi Imamura, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/813,525

(22) PCT Filed: Jan. 13, 2006
(86) PCT No.: PCT/JP2006/300787

§ 371 Date: Jul. 9, 2007

(30) Foreign Application Priority Data
Jan. 13, 2005 (JP) 2005-006367

(51) Int. Cl. H05K 9/00; H05K 3/34

(52) U.S. Cl. 361/818; 29/839

(57) ABSTRACT

A structure for attachment of a shield case to a circuit board. Electronic components are mounted at one face of the circuit board. The shield case is for covering the electronic components and blocking electromagnetic waves. The attachment structure includes toe portions, formed to protrude from the shield case, and holes formed in the circuit board, at which the toe portions can be inserted. The toe portions are fixed to the circuit board by being inserted into the holes and soldered to soldering lands at the other face of the circuit board. Thus, it is possible to prevent solder balls and solder flux entering the shield case, it is further possible to reserve space for soldering lands, with sizes that are required for fixing of the shield case, at a rear face of the circuit board, and it is possible to attach the shield case to the circuit board strongly.

### CROSS-REFERENCE TO RELATED APPLICATION

This application claims priority under 35 USC 119 from Japanese Patent Application No. 2005-006367, the disclosure of which is incorporated by reference herein.

### TECHNICAL FIELD

The present invention relates to a structure and process for attaching a shield case to a circuit board, and to a portable telephone at which an imaging module which is structured using this shield case attachment structure is installed.

### BACKGROUND TECHNOLOGY

At an imaging module, an imaging element, a lens and components such as an IC, which is a driver for driving the imaging element, and the like are integrated as a package. The imaging module is installed at an information terminal, such as a portable telephone or the like. Electronic components, such as a CCD and the like, are mounted at a circuit board which structures this imaging module. Electromagnetic waves are emitted from these electronic components, and the electromagnetic waves may cause impairment of communications functions of the information terminal. Accordingly, the electronic components mounted at the circuit board are covered with, for example, a shield case made of metal, and thus the electromagnetic waves are blocked (see Japanese Patent Application Laid-Open (JP-A) No. 2002-232099).

Now, as shown in FIG. 9, a shield case 104 is often fabricated by folding a metal plate, and gaps M are formed between neighboring side faces 104B. Further, a toe portion 106, which protrudes from the side faces 104B, is soldered to a soldering land 108, which is provided at a circuit board 102. Thus, the shield case 104 is fixed to the circuit board 102.

However, when a soldering operation is being performed, solder balls, solder flux and the like may be scattered, and may ingress through the gaps M into the shield case 104. If the solder balls/solder flux adhere to the electronic components, problems such as short-circuits and the like will occur.

Accordingly, as shown in FIG. 10, a shield case 112 is sometimes fabricated by a press-drawing process, such that gaps are not formed in a side wall 112B. When this shield case 112 in which there are no gaps in the side wall 112B is soldered to a circuit board, solder balls and solder flux do not enter into the shield case 112. However, because the shield case 112 is processed by the press-drawing process, fabrication time and costs are increased.

Moreover, when the shield case 112 is being soldered to a circuit board, the shield case 112 may be lifted from the circuit board, and there is a risk at such a time that solder flux may enter inside the shield case 112 through a gap between the shield case 112 and the circuit board.

Furthermore, in recent years, with the miniaturization of information terminals such as portable telephones and the like, there has been a tendency for the circuit board 102 to which the shield case 104 is to be attached to be reduced in size and, as shown in FIG. 9, for surface area of the soldering land 108 to be reduced. When the surface area of the soldering land 108 is small, work characteristics are adversely affected, in that an amount of time the soldering operation takes is longer and suchlike. Further, because the shield case 104 is fixed to the circuit board 102 only by the toe portion(s) 106 being soldered to the soldering land(s) 108, when a surface area of soldering is smaller, solder 110 is more likely to detach, and an attachment strength is weaker.

### DISCLOSURE OF THE INVENTION

Objects of the present invention are: firstly, to prevent solder balls, solder flux and the like entering into a shield case; secondly, to assure space for a soldering land with a required size without increasing size of a circuit board; and thirdly, to attach the shield case to the circuit board strongly.

A first aspect of the present invention is a structure for attachment of a shield case to a circuit board, an electronic component being mounted at one face of the circuit board, and the shield case being for covering the electronic component and blocking electromagnetic waves, the shield case-to-circuit board attachment structure including: a protrusion portion formed so as to protrude from the shield case; an insertion portion which is formed at the circuit board and at which the protrusion portion is insertable; and a fixing member, which fixes the protrusion portion that has been inserted at the insertion portion to another face of the circuit board.

According to the first aspect of the present invention, the insertion portion is formed in the circuit board at whose one face the electronic component is to be mounted. The protrusion portion protruding from the shield case is inserted into this insertion portion, and the protrusion portion is fixed at the other face of the circuit board by the fixing member. Thus, the shield case is attached to the circuit board.

In this manner, the protrusion portion is fixed to the circuit board at the other face of the circuit board, which is at the opposite side of the circuit board from the one face at which the electronic component is to be mounted. Therefore, there is no need to reserve space for fixing the shield case at the one face of the circuit board. Accordingly, it is possible to reduce size of the circuit board. Meanwhile, because space for attaching the protrusion portion is provided at the other face of the circuit board, this attachment space can be assured with sufficient size. Hence, attachment strength when the shield case has been attached to the circuit board can be raised.

Furthermore, because the protrusion portion of the shield case is fixed by the fixing member in the state in which the protrusion portion has been inserted into the insertion portion, the protrusion portion will not fall out from the insertion portion. Thus, detachment of the shield case from the circuit board is prevented. Therefore, it is not necessary to provide a member or the like at the shield case and/or the circuit board specifically for preventing detachment of the shield case from the circuit board. Thus, forms of the shield case and/or the circuit board can be simplified, leading to a reduction in costs.

Further again, because the shield case covering the one face of the circuit board is structured to be fixed to the circuit board at the other face thereof, even if the shield case is subjected to an impact, with this structure, the shield case is unlikely to detach from the circuit board.

In the first aspect of the present invention, the fixing member may include solder which fixes the protrusion portion to a soldering land, the soldering land being provided at the other face of the circuit board and being electrically connected with a grounding portion of the circuit board.

In the structure described above, the protrusion portion protruding from the shield case is soldered to the soldering land provided at the other face of the circuit board. Thus, the shield case is connected to an earth of the circuit board and is fixed.

That is, a soldering operation is performed at the other face of the circuit board. Therefore, solder balls and solder flux that are generated in the soldering operation scatter at the side of the other face of the circuit board, and will not ingress through any gap between the shield case and the circuit board.

Furthermore, even with a shield case which is fabricated by folding a metal plate, that is to say, which has gaps between side wall portions, there is no risk of the solder balls or solder flux entering into the shield case. Therefore, there is no need to fabricate the shield case by a press-drawing process in order to prevent ingression of solder balls and solder flux into the shield case, and the shield case can be produced inexpensively, leading to a reduction in costs.

When the soldering operation is being performed, it is necessary to heat the protrusion portion with a soldering iron or the like. At such a time, heat applied to a protrusion portion would be conducted to a main body of a shield case and dissipated therefrom. However, the protrusion portion is fixed to the circuit board at the opposite side thereof from the side at which the main body of the shield case is disposed. Thus, because the circuit board is interposed between the protrusion portion and the shield case main body, a heating characteristic (heating efficiency) of the protrusion portion is improved, and the soldering operation can be performed more smoothly.

In the first aspect of the present invention, the fixing member may include a clip which is applied to the protrusion portion and which contacts with a grounding portion of the circuit board, the clip fixing and electrically connecting the protrusion portion to the circuit board.

With the structure described above, the clip is applied to the protrusion portion projecting at the other face of the circuit board, and the clip is conductively connected with the grounding portion of the circuit board. Thus, the protrusion portion is both electrically connected to the circuit board and fixed to the circuit board.

Accordingly, because solder is not employed, there will be no scattering of solder balls or solder flux, and there is no risk of entry thereof into the shield case. Moreover; in comparison with a case in which a shield case is attached to a circuit board using solder, an attachment operation is simple.

In the first aspect of the present invention, the insertion portion may include at least one of a hole and an incision which is formed in an end face of the circuit board.

With the structure described above, because the insertion portion is formed as a hole or an incision, when the protrusion portion is inserted into the insertion portion, the shield case is positioned relative to the circuit board. Therefore, because positioning of the shield case relative to the circuit board is implemented when the shield case is being attached to the circuit board, there is no need to provide members for positioning at the shield case and the circuit board, and forms of the shield case and the circuit board are simplified.

A second aspect of the present invention is an electronic component module including: a circuit board, at one face of which an electronic component is mounted; a shield case which covers the electronic component, for blocking electromagnetic waves; a protrusion portion formed so as to protrude from the shield case; an insertion portion which is formed at the circuit board and at which the protrusion portion is insertable; and a fixing member, which fixes the protrusion portion that has been inserted at the insertion portion to another face of the circuit board.

A third aspect of the present invention is a portable telephone at which an imaging module is installed, the imaging module including: a circuit board, at one face of which an electronic component is mounted; a shield case which covers the electronic component, for blocking electromagnetic waves; a protrusion portion formed so as to protrude from the shield case; an insertion portion which is formed at the circuit board and at which the protrusion portion is insertable; and a fixing member, which fixes the protrusion portion that has been inserted at the insertion portion to another face of the circuit board.

A fourth aspect of the present invention is a process for assembling an electronic component module, including: preparing a circuit board which includes an insertion portion and at one face of which an electronic component is mounted; preparing a shield case for blocking electromagnetic waves, the shield case having been formed with a protrusion portion protruding therefrom; disposing the shield case on the circuit board such that the shield case covers the electronic component and the protrusion portion is inserted through the insertion portion of the circuit board; and fixing an end portion of the protrusion portion that has been inserted through the insertion portion to another face of the circuit board, with a fixing member.

With the above-described structures of the present invention, the present invention is capable of preventing solder balls and solder flux from entering inside a shield case. Furthermore, even when space for a soldering land with a required size is to be assured, a circuit board is not increased in size. Moreover, it is possible to strongly attach the shield case to the circuit board.

### BRIEF DESCRIPTION OF THE DRAWINGS

FIG. 1 is a perspective view showing a structure for attaching a shield case to a circuit board, which relates to an embodiment of the present invention.

FIG. 2 is a perspective view showing the shield case-to-circuit board attachment structure relating to the embodiment of the present invention.

FIG. 3 is a perspective view showing the shield case-to-circuit board attachment structure relating to the embodiment of the present invention.

FIG. 4A is a perspective view showing structure of a portable telephone at which an imaging module is installed, in which imaging module the shield case-to-circuit board attachment structure relating to the embodiment of the present invention is employed, as viewed from a control face.

FIG. 4B is a perspective view showing structure of the portable telephone, as viewed from a rear face.

FIG. 5 is a sectional view showing general structure of the imaging module in which the shield case-to-circuit board attachment structure relating to the embodiment of the present invention is employed.

FIG. 6A is a perspective view showing a structure for attaching a shield case to a circuit board which relates to another embodiment of the present invention.

FIG. 6B is a sectional view showing the shield case-to-circuit board attachment structure relating to the other embodiment of the present invention.

FIG. 7 is a perspective view showing a shield case-to-circuit board attachment structure relating to yet another embodiment of the present invention.

FIG. 8 is a perspective view showing a shield case-to-circuit board attachment structure relating to still another embodiment of the present invention.

FIG. 9 is a perspective view showing a conventional structure for attaching a shield case to a circuit board.

FIG. 10 is a perspective view of a conventional shield case.

### BEST MODE FOR CARRYING OUT THE INVENTION

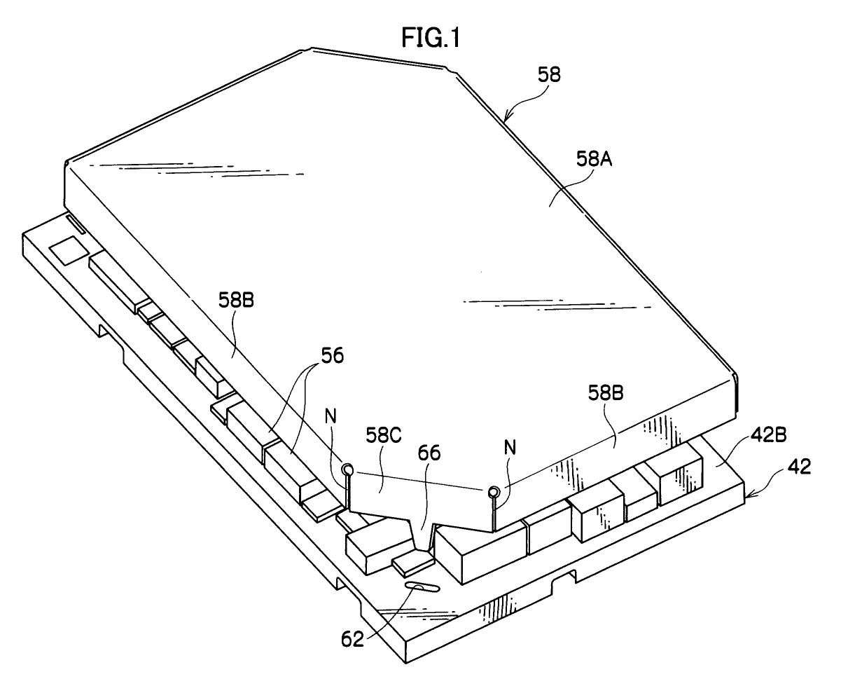

FIG. 1 shows a structure for attaching a shield case to a circuit board of an embodiment of the present invention.

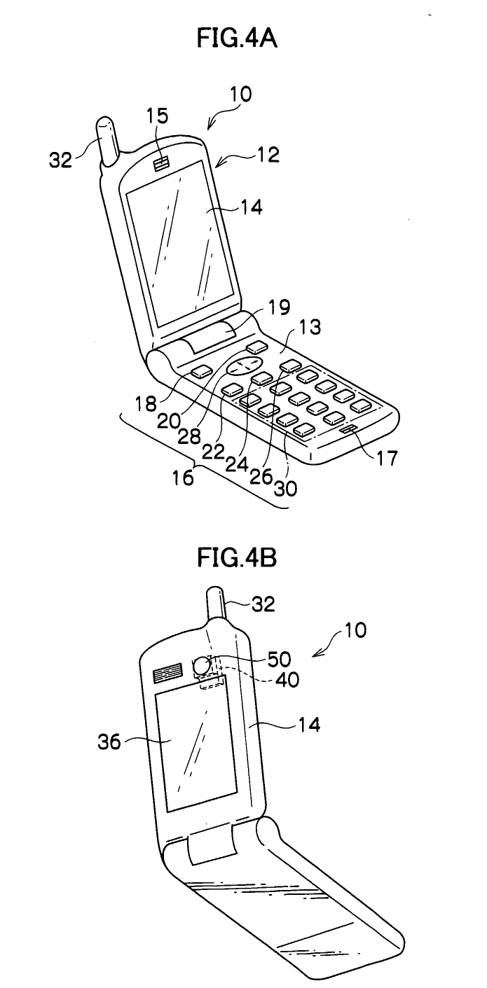

Electronic components 56 such as resistors, capacitors, semiconductor chips and the like are mounted at a front face 42B of a circuit board 42. In order to protect these electronic components 56, a box-like shield case 58 is attached to the front face 42B of the circuit board 42. A case made of metal is employed as the shield case 58. Because the shield case 58 is attached to the circuit board 42, electromagnetic waves which are emitted from the electronic components 56 on the circuit board 42 will be blocked by the shield case 58 and will not affect, for example, communications functions of a portable telephone 10 (see FIGS. 4A and 4B).

The shield case 58 is formed in a box shape with a substantially rectangular shape in plan view, with opposing corner portions thereof cut away to form short side faces 58C. A toe portion 66 is projected from a substantially central portion of each short side face 58C. The toe portion 66 is formed in a substantially rectangular shape, with a roundness (a curved profile) formed at a distal end portion thereof.

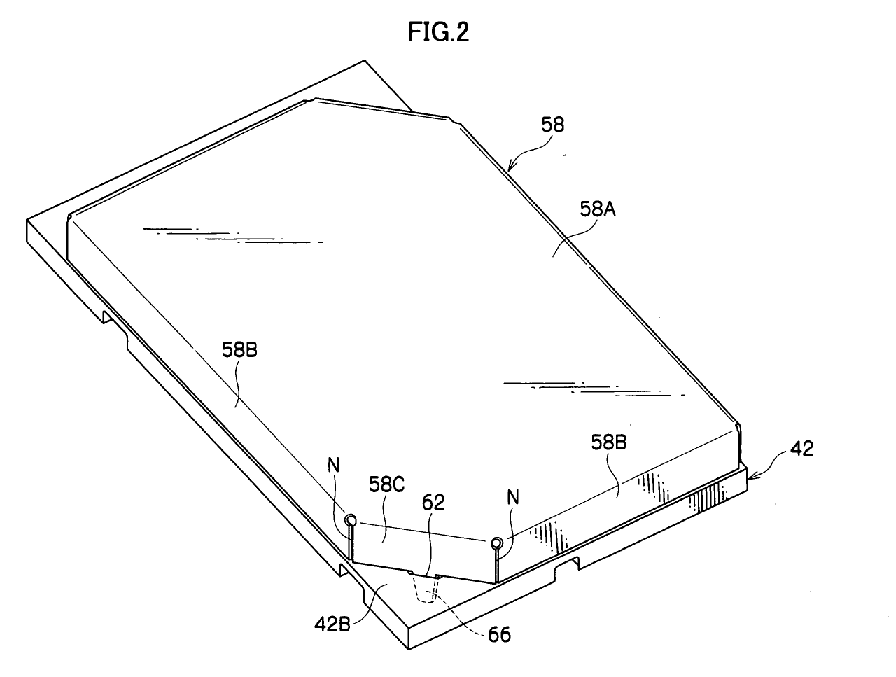

Hole portions 62 with round-ended oblong shapes are formed at vicinities of corresponding corner portions of the circuit board 42. As shown in FIG. 2, when the shield case 58 is placed on the circuit board 42, the toe portions 66 are inserted into the hole portions 62. When the toe portions 66 are thus inserted into the hole portions 62, the shield case 58 is positioned with respect to the circuit board 42. The shield case 58 is formed by a step of stamping out the shield case 58 from sheet metal, in a state in which a ceiling face 58A, side faces 58B and the short side faces 58C are folded out flat, and a step of folding the side faces 58B and the short side faces 58C down to be substantially perpendicular with respect to the ceiling face 58A. Here, gaps N are formed between the side faces 58B and between the side faces 58B and the short side faces 58C.

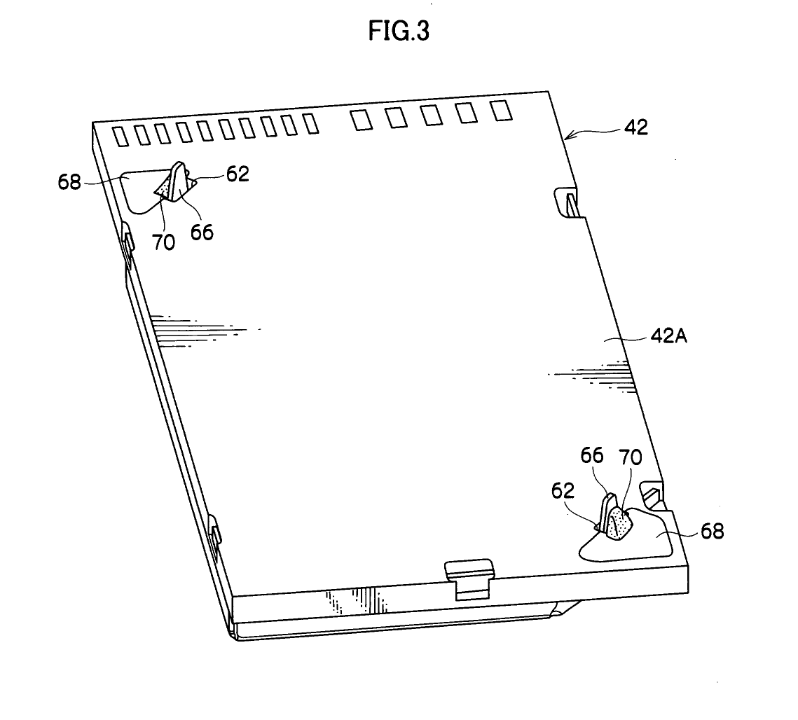

FIG. 3 is a view showing the state when the shield case 58 is placed on the circuit board 42, viewing the circuit board 42 from a rear face 42A.

A soldering land 68 with a substantially triangular shape is provided in a vicinity of each hole portion 62 at the rear face 42A of the circuit board 42. The soldering land 68 is connected with a grounding portion (not shown) which is provided at the circuit board 42. The toe portions 66 of the shield case 58 that have been inserted into the hole portions 62 from the front face 42B (mounting face) of the circuit board 42 are fixed by being soldered to the soldering lands 68. Hence, electromagnetic waves which are emitted from the electronic components 56 mounted at the front face 42B of the circuit board 42 (see FIG. 1) are propagated in the shield case 58 and are absorbed by the grounding portion via the soldering lands 68. As a result, the electromagnetic waves emitted from the electronic components 56 can be prevented from exerting effects on communications functions of the portable telephone 10 (see FIGS. 4A and 4B).

Now, the portable telephone 10 will be briefly described. FIGS. 4A and 4B show the portable telephone 10, at which an imaging module 40 is installed. The imaging module 40 is formed using the shield case attachment structure of the present invention.

As shown in FIG. 4A, a display portion 12 and a control portion 13 of the portable telephone 10 are foldably joined by a hinge 19. The display portion 12 is equipped with a liquid crystal screen 14 and a speaker 15. The control portion 13 is equipped with a microphone 17. Furthermore, switches 16 are provided at the control portion 13. The switches 16 are for implementing inputs of various instructions. In the present embodiment, a photography button 18, a call button 20, a still image button 22, a moving image button 24, a self-photography button 26, an up/down arrow key 28 and a ten-key pad 30 function as the switches 16. The up/down arrow key 28 is operated by a user when arbitrary menu items are to be selected from various menus, which are displayed the liquid crystal screen 14 and a rear face liquid crystal screen 36 (see FIG. 4B). The ten-key pad 30 is operated by a user when data such as numbers and the like are to be inputted. Further, an antenna 32 for external communications is provided at an upper face of the display portion 12 of the portable telephone 10, and functions as a communications portion.

As shown in FIG. 4B, the imaging module 40 (which will be described in more detail below) is incorporated at the display portion 12, and an aperture lens 50 of a lens barrel 48 faces out at the rear face of the display portion 12.

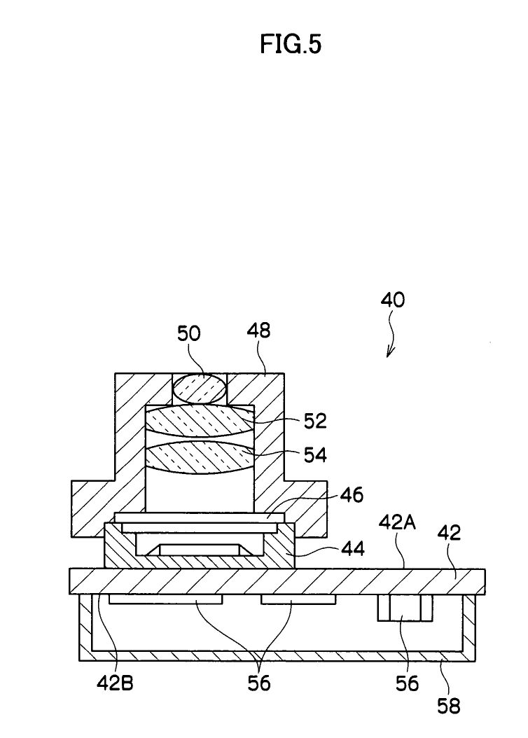

Next, structure of the imaging module 40 will be described in accordance with FIG. 5.

The imaging module 40 is equipped with the flat board-form circuit board 42, which is formed of a non-metallic ceramic or the like. An imaging chip 44 is disposed at one face (the rear face) 42A of the circuit board 42. The imaging chip 44 is structured with a CCD image sensor, a CMOS image sensor or the like which serves as an imaging element. An infrared light (IR) blocking filter 46 is disposed on the imaging chip 44. The infrared blocking filter 46 and the imaging chip 44 are covered with the lens barrel 48. The aperture lens 50 and two lenses 52 and 54, for focusing a subject image onto the imaging chip 44, are attached to the lens barrel 48.

At another face (the front face) 42B of the circuit board 42, the electronic components 56 such as resisters, capacitors, semiconductor chips and the like are mounted. In order to protect these electronic components 56, the box-like shield case 58 is attached to the front face 42B of the circuit board 42.

Next, operations of the present embodiment of the invention will be described.

As shown in FIG. 3, because the toe portions 66 are soldered to the soldering lands 68 formed at the rear face 42A of the circuit board 42 (i.e., the face of the side thereof which is opposite from the side at which the electronic components 56 are mounted), there is no need to reserve space for fixing the shield case 58, that is, space for forming the soldering lands 68, at the front face 42B of the circuit board 42. Accordingly, it is possible to reduce size of the circuit board 42.

Further, because the soldering lands 68 are formed at the rear face 42A of the circuit board 42, the soldering lands 68 can be formed with adequate sizes. Therefore, an attachment strength when the shield case 58 is fixed to the circuit board 42 can be raised.

Further still, solder balls, solder flux and the like that are generated by a soldering operation will be scattered at the rear face 42A side of the imaging chip 44, and will not ingress through any gap between the shield case 58 and the circuit board 42.

Further again, even when the shield case 58 is fabricated by folding up sheet metal, which is to say when there are gaps N between the side faces 58B and between the side faces 58B and the short side faces 58C (see FIG. 2), there is no risk of solder balls or solder flux entering into the shield case 58. Accordingly, because entry of solder balls and solder flux into the shield case 58 is blocked, there is no need to fabricate the shield case 58 by a press-drawing process. Therefore, the shield case 58 can be produced inexpensively, leading to a reduction in costs.

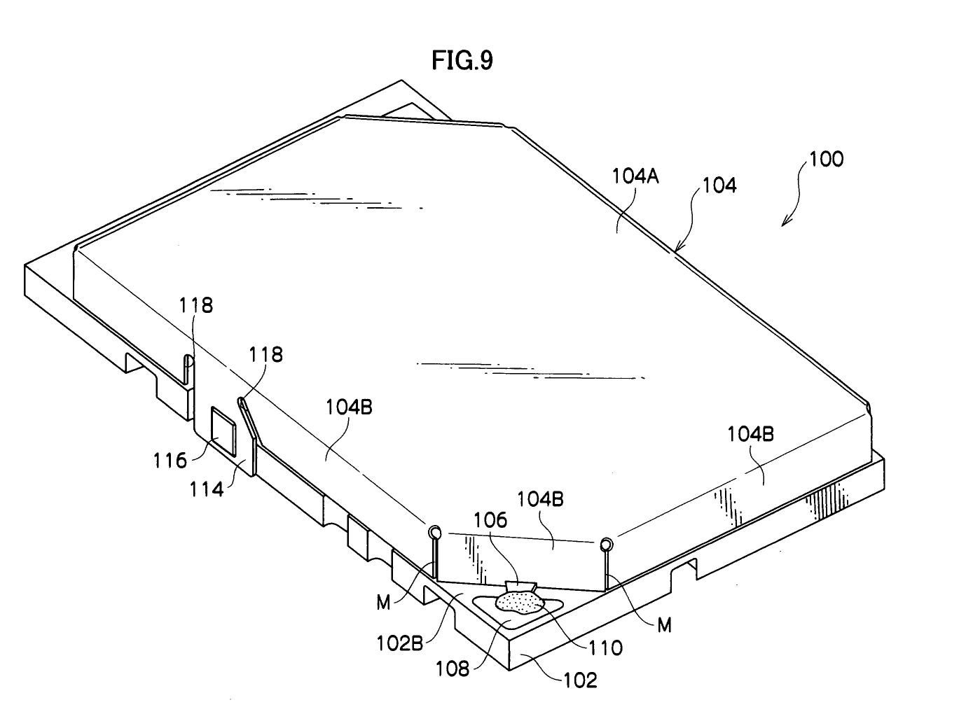

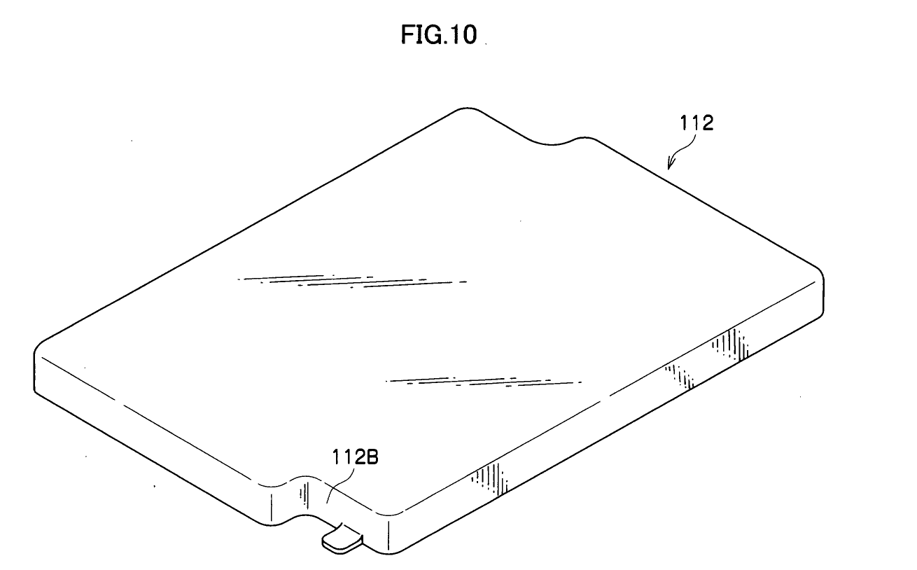

Further yet, positioning of the shield case 58 relative to the circuit board 42 is implemented by the toe portions 66 of the shield case 58 being inserted into the hole portions 62 formed in the circuit board 42. Therefore, there is no need to provide dedicated portions for implementing positioning of the shield case 58 relative to the circuit board 42, as is shown in FIG. 9, in which positioning pawls 114 and engaging portions 116, which engage with the positioning pawls 114, are provided at one and another of the shield case 104 and the circuit board 102.

Moreover, solder 70 is attached to each toe portion 66 which has been inserted through the hole portion 62 of the circuit board 42. The solder 70 has a protruding form and prevents disengagement of the toe portion 66 from the hole portion 62. Accordingly, there is no need to provide members or the like for preventing detachment of the shield case 58 from the circuit board 42 at the shield case 58 and/or the circuit board 42.

As a consequence, forms of the shield case 58 and the circuit board 42 are kept simple, and it is possible to keep down fabrication costs of the shield case 58 and the circuit board 42.

Furthermore, the shield case 58 covering the front face 42B of the circuit board 42 is structured to be fixed to the circuit board 42 at the rear face 42A thereof. Hence, with this structure, the shield case 58 is unlikely to detach from the circuit board 42 even if the shield case 58 is subjected to impacts.

Now, when the toe portion 66 is being soldered to the soldering land 68, it is necessary to heat the toe portion 66 with a soldering iron or the like. At such a time, in the structure shown in FIG. 9, the toe portion 106 of the shield case 104 is folded out substantially perpendicularly from the side face 104B and the toe portion 106 is soldered to the soldering land 108, which is provided at a face 102B of the circuit board 102 at which face an IC (electronic component) and suchlike are mounted. In this case, when the toe portion 106 is heated, the heat is dissipated through the main body of the shield case 104.

Correspondingly, as shown in FIG. 3, the toe portion 66 protrudes at the rear face 42A side of the circuit board 42, and the toe portion 66 is soldered to the soldering land 68 with the circuit board 42 interposed between the toe portion 66 and the main body of the shield case 58. In this case, heat that is applied to the toe portion 66 is blocked by the circuit board 42 and is less susceptible to being conducted to the main body of the shield case 58. Therefore, there will be little dissipation through the main body of the shield case 58. As a result, a heating characteristic (heating efficiency) of the toe portion 66 is improved, and an operation of soldering can be performed more smoothly.

Furthermore, in the case of the conventional shield case 104 shown in FIG. 9, the shield case 104 is fabricated by a step of cutting from sheet metal, a step of bending the side faces 104B to be substantially perpendicular to a floor face 104A, and a step of folding the toe portion 106 from the side face 104B. In addition, slits 118 are formed between the positioning pawls 114 and the side face 104B. Because these slits 118 would complicate implementation of the step of cutting from sheet metal, the slits 118 are formed by a separate step.

In contrast, the shield case 58 of the present embodiment is fabricated just by a step of cutting from sheet metal and a step of bending the side faces 58B and short side faces 58C to be substantially perpendicular to the ceiling face 58A. Therefore, because the process of fabricating the shield case 58 is shorter, fabrication costs can be kept lower.

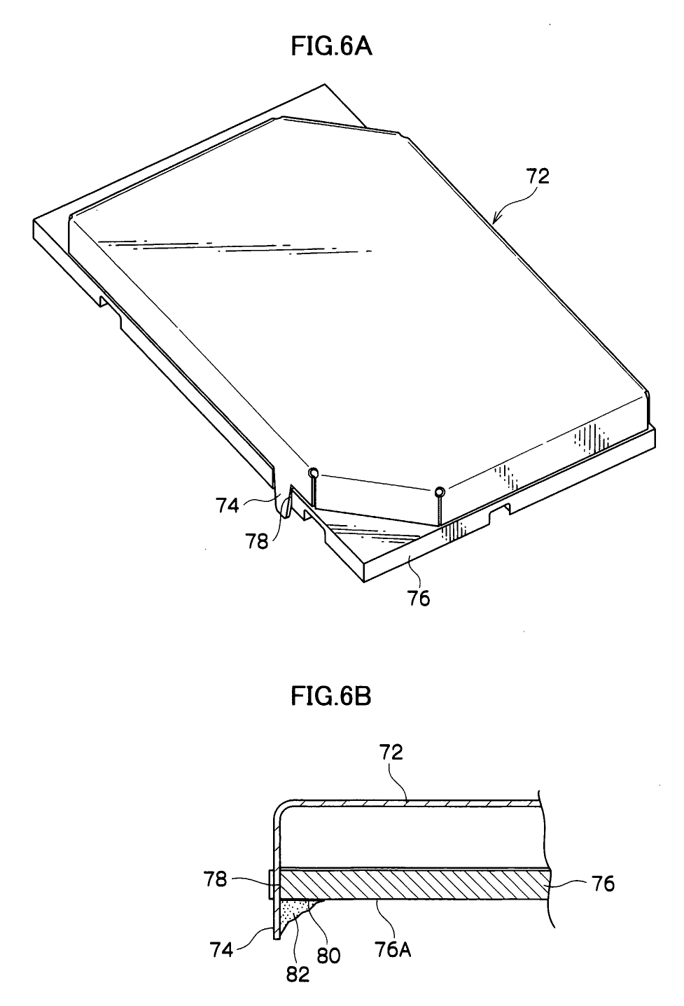

Now, the present embodiment has a structure in which the toe portions 66 are inserted into the hole portions 62 of the circuit board 42. However, as shown in FIG. 6A, an incision portion 78 could be formed at each of an opposing pair of sides of a circuit board 76, and toe portions 74 formed at a shield case 72 could be fixed at the incision portions 78 with, as shown in FIG. 6B, the toe portions 74 being soldered to soldering lands 80 provided at a rear face 76A of the circuit board 76. Further, in such a case, the toe portion 74 which is fixed at each incision portion 78 may be folded over to the circuit board 76 side thereof. Hence, because the toe portion 74 is resistant to displacement from the incision portion 78, a soldering operation is easier.

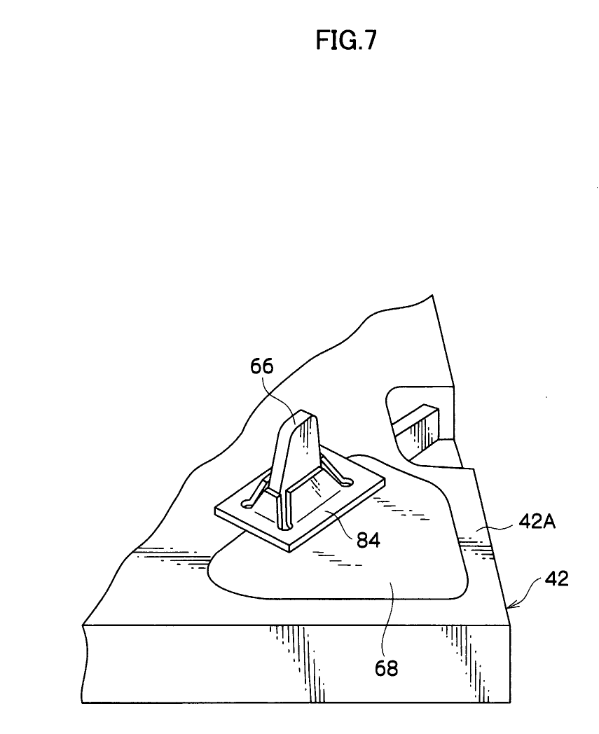

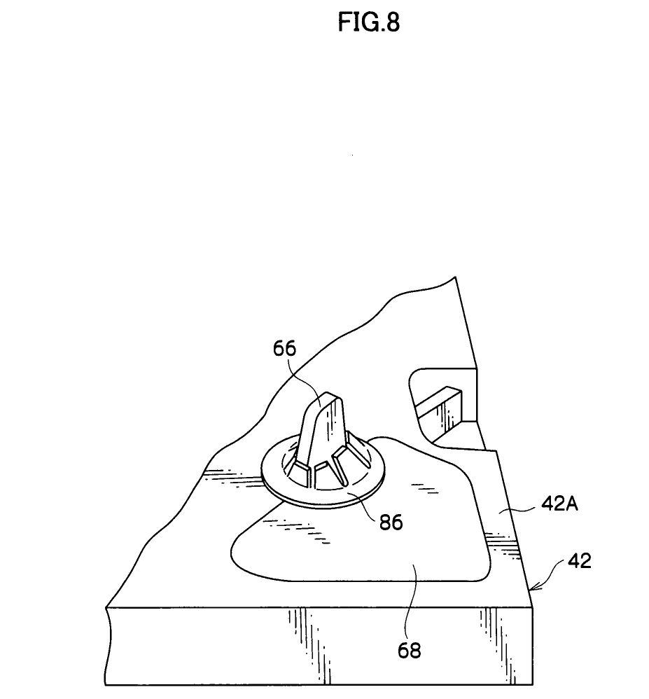

Furthermore, the present embodiment has a structure in which the shield case 58 is attached to the circuit board 42 by the toe portion 66 being soldered to the soldering land 68. However, as shown in FIGS. 7 and 8, structures are also possible in which the toe portion 66 fits into a clip 84 or 86 which is formed at a conductive member, and the clip 84 or 86 is contacted with the soldering land 68. In such a case, because there is no need to solder the clip 84 or 86, there will be no scattering of solder balls or solder flux, and there will be no risk of the same entering into the shield case 58. Moreover, in comparison with the case in which the shield case 58 is attached to the circuit board 42 using solder, an attachment operation is simple.

### INDUSTRIAL APPLICABILITY

The present invention can be broadly applied to electronic circuit boards at which it is required to shield electromagnetic waves by covering with a shield case, such as at imaging modules of portable telephones.

1. A structure for attachment of a shield case to a circuit board, an electronic component being mounted at one face of the circuit board, and the shield case being for covering the electronic component and blocking electromagnetic waves, the shield case-to-circuit board attachment structure comprising:
a protrusion portion formed so as to protrude from the shield case;
an insertion portion which is formed at we circuit board and at which the protrusion portion is insertable; and
a fixing member, which fixes the protrusion portion that has been inserted at the insertion portion to another face of the circuit board.

2. The shield case-to-circuit board attachment structure of claim 1, wherein the fixing member comprises solder which fixes the protrusion portion to a soldering land, the soldering land being provided at the other face of the circuit board and being electrically connected with a grounding portion of the circuit board.

3. The shield case-to-circuit board attachment structure of claim 1, wherein the fixing member comprises a clip which is applied to the protrusion portion and which contacts with a grounding portion of the circuit board, the clip fixing the protrusion portion to the circuit board and electrically connecting the protrusion portion with the grounding portion.

4. The shield case-to-circuit board attachment structure of claim 1, wherein the insertion portion comprises at least one of a hole and an incision which is formed in an end face of the circuit board.

5. An electronic component module comprising:
a circuit board, at one face of which an electronic component is mounted;
a shield case which covers the electronic component, for blocking electromagnetic waves;
a protrusion portion formed so as to protrude from the shield case;
an insertion portion which is formed at the circuit board and at which the protrusion portion is insertable; and
a fixing member, which fixes the protrusion portion that has been inserted at the insertion portion to another face of the circuit board.

6. The electronic component module of claim 5, wherein the fixing member comprises solder which fixes the protrusion portion to a soldering land, the soldering land being provided at the other face of the circuit board and being electrically connected with a grounding portion of the circuit board.

7. The electronic component module of claim 5, wherein the fixing member comprises a clip which is applied to the protrusion portion and which contacts with a grounding portion of the circuit board, the clip fixing the protrusion portion to the circuit board and electrically connecting the protrusion portion with the grounding portion.

8. The electronic component module of claim 5, wherein the insertion portion comprises at least one of a hole and an incision which is formed in an end face of the circuit board.

9. A portable telephone at which an imaging module is installed, the imaging module comprising:
a circuit board, at one face of which an electronic component is mounted;
a shield case which covers the electronic component, for blocking electromagnetic waves;
a protrusion portion formed so as to protrude from the shield case;
an insertion portion which is formed at the circuit board and at which the protrusion portion is insertable; and
a fixing member, which fixes the protrusion portion that has been inserted at the insertion portion to another face of the circuit board.

10. A process for assembling an electronic component module, comprising:
preparing a circuit board which includes an insertion portion and at one face of which an electronic component is mounted;
preparing a shield case for blocking electromagnetic waves, the shield case having been formed with a protrusion portion protruding therefrom;
disposing the shield case on the circuit board such that the shield case covers the electronic component and the protrusion portion is inserted through the insertion portion of the circuit board; and
fixing an end portion of the protrusion portion that has been inserted through the insertion portion to another face of the circuit board, with a fixing member.

11. The electronic component module assembly process of claim 10, wherein the fixing member includes solder which fixes the protrusion portion to a soldering land, the soldering land being provided at the other face of the circuit board and being electrically connected with a grounding portion of the circuit board.

12. The electronic component module assembly process of claim 10, wherein the fixing member includes a clip which is applied to the protrusion portion and which contacts with a grounding portion of the circuit board, the clip fixing the protrusion portion to the circuit board and electrically connecting the protrusion portion with the grounding portion.

13. The electronic component module assembly process of claim 10, wherein the insertion portion includes at least one of a hole and an incision which is formed in an end face of the circuit board.
